(19) United States
(12) Patent Application Publication
(10) Pub. No.: US 2010/0326486 A1
(43) Pub. Date: Dec. 30, 2010

(54) THERMAL TRANSMITTER FOR ENERGY USE OF THERMAL RADIATION AND CONVECTION

(76) Inventors: Wolfgang Beck, Blankenburg (DE); Anja Krichler, Halberstadt (DE)

Correspondence Address: PARFOMAK, ANDREW N.;NORRIS MCLAUGHLIN & MARCUS PA, 875 THIRD AVE, 8TH FLOOR, NEW YORK, NY, 10022, US

(21) Appl. No.: 12/811,140

(22) PCT Filed: Dec. 29, 2008
(86) PCT No.: PCT/EP08/68330

§ 371 Date: Sep. 14, 2010

(30) Foreign Application Priority Data
Dec. 31, 2007 (DE) 102007055937.4

(51) Int. Cl. H01L 35/30; H01L 35/32

(52) U.S. Cl. 136/203

(57) ABSTRACT

A thermogenerator is fitted with a thermal transmitter arranged between a thermal storage battery and a thermal diffuser. The transmitter preferably forms a thermal barrier with imbedded Peltier elements acting as thermal gates between the accumulator and the diffuser.

### TECHNICAL FIELD

The present invention relates in general to an apparatus and a method for generating electrical energy from thermal energy whilst simultaneously using the accumulated heat.

In particular, the present application relates to a thermal transmitter for energy use of thermal radiation and convection.

### PRIOR ART

In the search for efficient use of energy sources, the heat sources of the Sun, Earth and the secondary heat sources from all possible technical and natural processes are increasingly becoming the focus of scientific-technical research and developments.

In numerous methods, the use of solar energy and other heat sources is described.

Common to all these at the present time is still the low efficiency, in particular of electrical energy generation. The efficiency is considered to be the ratio of the usable to the used energy.

For Illustration

Conventional light bulbs/glow lamps convert about 3 to 4% of the energy used into light, photovoltaic systems or solar cells presently reach an efficiency of 11 to 17%, thermal solar systems can convert between 25 and 40% of the solar radiation. Similar relationships are also presented in the use of terrestrial heat or secondary energy (waste heat from technical processes).

Available as usable energy sources in the sense of the patent description are
solar energy with its thermal radiation
terrestrial heat in the sense of geothermal energy
secondary technology cycles (waste heat).
   It is common to all the processes that the available thermal energy is raised to a higher usable energy level by means of heat exchangers or combined heat and power.

e.g. Function of a Thermal Solar System for Use as a Thermal Energy Source

The central feature of a thermal solar system is the collector. The most widely used design of a collector, the flat-plate collector, consists of a selectively coated absorber (predominantly of metal) which is used for absorption (“uptake”) of the incident solar radiation and its conversion into heat. In order to minimise thermal losses, this absorber is embedded in a thermally insulated box with a transparent cover (mostly glass).

The absorber has a heat transfer fluid (usually a mixture of water and ecologically safe antifreeze) flowing therethrough, which circulates between collector and hot water storage device.

These absorbers are provided with special coatings to increase the efficiency.

Description of these Conventional Coatings

Absorber Coatings

In order to achieve the highest possible absorption of solar energy, the surface of the absorber facing the sun is either coloured black or provided with a special coating which acts selectively, i.e. absorbs the shorter-wavelength solar energy coming from outside as efficiently as possible (absorption) and only inefficiently releases the longer-wavelength thermal energy of the absorber.

Modern coatings usually have a bluish iridescent colour. With 91 to 96 percent absorption, they achieve similarly high values to the previously predominantly used (black iridescent) black chrome coating but at the same time significantly lower emission values, i.e. lose less heat due to irradiation. As a result, they achieve overall significantly higher power values than merely black-painted absorbers but also measurably and perceptibly higher values than black-chrome coated absorbers.

The absorber should collect direct and diffuse solar radiation as efficiently as possible and convert it into heat (absorption). At the same time, it should release as little heat as possible again in the form of radiation (emission). In addition, the absorber itself should be heat- and UV-resistant in the long term.

In hot countries, absorbers merely “coated” with so-called solar varnish are frequently used. This solar varnish is very heat-resistant and usually black in order to achieve the best possible absorption values for solar radiation. At the same time, however, the emission values in the middle infrared are very high—some of the collected heat is therefore emitted again.

In order to minimise energy losses, a so-called highly selective collector coating is used. Absorption values of about 94% for sunlight (0.4 to 0.8 μm wavelength) and emission values of less than 6% are thus achieved for the radiation (infrared having wavelengths around 7.5 μm) re-emitted as a result of the intrinsic temperature of the absorber.

One of the first coatings with selective absorption which could be mass-produced was the so-called black “Chrome” coating. This was applied by a galvanic method to the absorber plate consisting of copper or aluminium. In very simple terms, this consists of microscopic chromium hairs which collect the sunlight between them but as a result of their small size, emit little at larger wavelengths.

Until recently the black chrome coating dominated the market. In the meantime however, newer coatings not only allow higher efficiencies but are also considered to be more environmentally friendly even from production aspects—primarily because of dispensing with galvanic processes. An alternative to black chrome now no longer available on the market was a—similarly applied—nickel coating (“black nickel”).

The most widely used today is a titanium-based sputtered layer having a blue colour which has slightly inferior absorption values compared with black chrome but on the other hand achieves significantly lower emission values and therefore overall a better efficiency. The first coatings of this type ready for series production were developed in the form of titanium nitrite oxide coatings in Germany and brought onto the market by TiNOX. Theoretically other colours are also possible with this coating depending on the layer structure; so far however these do not achieve comparable power values.

A further development of the late nineties is the “Sunselect” coating of the glass and coating manufacturer Interpane, a ceramic metal structure (presumably also titanium-based) which like the titanium nitrite oxide coatings is applied by the vacuum sputtering method and is also iridescent blackish blue.

Both coatings can so far only be applied to absorber plates made of copper; corresponding techniques for aluminium absorbers have only recently come onto the market. However, these aluminium absorbers also use copper piping connected to the absorber by laser welding for the removal of heat by means of the “solar fluid”.

In addition to the coating, absorbers from different manufacturers also differ in their fundamental structure. Full-area absorbers consisting of a single absorber sheet are frequently encountered. In these absorbers the piping is soldered or welded on the back in serpentine or meander form or in harp form. In addition, there are strip absorbers consisting of individual fins, possibly 10-15 cm narrow strips each having a thin tube welded on the back. The fins are then soldered at both ends into a manifold so that a type of “harp” is formed. A third design comprise the cushion absorbers. Like full area absorbers, these consist of a single continuous absorber plate onto the back of which, however, a moulded second plate is applied instead of a pipe. The heat transfer fluid flows between these two plates.

In principle, full-area absorbers have the best power values. Since initially the manufacturers of the new highly selective coating could only process copper plates which did not exceed a certain width, predominantly absorber fins were still used primarily in older collector modules. Absorber plates in widths up to 1200 mm are now available which makes it possible to achieve great flexibility in the absorber geometry. In contrast to this, absorber fins only allow tubing in harp form, but on the other hand fins can be adapted more simply to the roof shape (tailor-made collectors).

The prior art presented here already exhibits a large amount of production costs.

Thermal solar systems are put into operation by means of a solar regulator. As soon as the temperature at the collector exceeds the temperature in the storage device by a few degrees, the regulator switches on the solar circuit circulating pump and the heat transfer fluid transports the heat absorbed in the collector into the heat exchanger in order to use the thermal energy generated in a hot water storage tank.

All the other alternative usable energy sources function according to the same principle.

Available thermal energy is therefore collected and made usable by means of a heat exchanger medium, i.e. thermal energy is brought to a higher energy level but ultimately remains thermal energy.

The generation of electrical energy from these alternative energy sources is characterised by a low efficiency.

Historically thermocouples have been known for a very long time.

Thermocouples are always formed at the point at which two different metals are connected in an electrically conducting manner. At this connection point a temperature-dependent contact voltage is formed, the so-called Seebeck effect. This contact voltage (thermovoltage) depends on the two metals and the temperature difference between the connection point (measurement point) and the open ends (attachment point).

These ends must be extended with the same metal (thermal conductor) or with metals having the same thermoelectric properties (compensating line) as the thermocouple wires as far as a zone of known temperature, the reference point.

These elements are used as sensors. Energy usage of the thermovoltage is feasible and has already been sufficiently described but ultimately fails on the efficiency. An illustration is given in FIG. 1.

The Peltier effect is the reverse of the Seebeck effect and should be used in the sense of the patent description. When an electrical current flows through two successively switched contact points of two different semiconductors or conductors, on one leg thermal energy is absorbed and on the other leg thermal energy is released. The diagram of a Peltier element is reproduced in FIG. 2. By implication this means that when there is a continuous heat flow through the respective contact points or the legs of the semiconductor element, electric current is generated.

The utility model DE 20 2007 005 127 U1 attempts to present the use of the Peltier element as technically effective. In so doing the utility model takes as its starting point a warm flowing medium in a tube-in-tube, a cooler liquid being located in the centre thereof, separated by a ring of semiconductor block elements which are doped according to the Peltier-Seeback effect. The utility model specification proceeds exclusively from a method of converting thermal energy into electrical energy in a closed cycle.

The utility model does not say where the thermal energy comes from and how the energy balance looks. Consequently the description presents energetically a pure power generator which is comparable to a coal-fired power station in which coal is burnt to produce thermal energy and in turn to generate electrical power from this.

The utility model specification also does not say that for an energy use according to the Seebeck-Peltier effect, a heat flow through the Peltier element is absolutely essential and this is dependent on existing temperature gradients for its efficient use.

In contrast to the utility model description, alternative energy sources which are available as energy donors are used in the present invention. These are
solar,
geo- and
secondary thermal sources.

Another technical delimitation from the utility model protection described arises from the technical approach to the solution. The system described is based on a tube-in-tube through which flow takes place and is ultimately confined to this geometrical configuration. The solution according to the present invention is considerably more extensive and allows an absolutely geometrically free formation so that the thermogenerator can be freely adapted geometrically to the respective technical requirements.

The solution according to the invention is further aimed at using the heat source for recovering electrical energy and the further use of the available thermal energy.

It can thus be deduced as a significant difference from the prior art that the technical solution of the utility model is a pure energy converter from heat into electrical energy whereas the system according to the invention is a system for using alternative energy sources which are available to generate electrical and thermal energy equally without using a synthetic energy source as heat donor.

Photovoltaic systems which in particular use the UV spectrum of the sunlight are further known for generating electrical energy. At the present time corresponding photovoltaic systems are being developed which however have so far not gone beyond the efficiency of 11 to 17% already specified. The high weights of the solar cells, the costs and the disturbing aesthetics in some cases are found to be particularly disadvantageous.

### SUMMARY OF THE INVENTION

The invention relates to a thermogenerator according to each single one of the patent claims 1 to 18 and its uses according to each single one of patent claims 19 to 22.

The invention relates inter alia to a thermal closure element consisting of a solvent-free freely mouldable liquid plastic based on a hydroxylene and/or aminofunctional reaction partner for isocyanate, wherein the solvent-free coating material is formed from two reactive components, wherein component A consists of an aliphatic isocyanate and/or mixtures thereof and component B consists of an 80 to 99% fraction of binder wettable with component A, based on a hydroxylene and/or aminofunctional reaction partner and/or mixtures thereof, and wherein component B contains a maximum fraction of 10% thermochromic pigments, 0% to 7% stabilisers and 0% to 3% of adjuvants.

This thermal closure element is preferably one in which nanoscalable fillers in powder form and/or in the form of a dispersion are additionally added to component B, which fillers form specific properties in the coating material which after curing effect a change in the surface hardness, the abrasiveness and/or the UV stability and/or serve to achieve surface effects and to achieve a fungicidal or an antifouling effect.

The invention further relates to a thermal storage battery consisting of a solvent-free freely mouldable liquid plastic based on a hydroxylene and/or aminofunctional reaction partner for isocyanate wherein the solvent-free coating material which is formed from two reactive components, wherein component A consists of an aliphatic isocyanate and/or mixtures thereof and component B consists of a 65% to 98% fraction of binder wettable with component A, based on a hydroxylene and/or aminofunctional reaction partner and/or mixtures thereof, and wherein component B contains a fraction of 0.00025% to 5% functionalised and/or non-functionalised carbon nanotubes, 0% to 20% of nanoscalable fillers and/or a dispersion of nanoscaled fillers in the form of primary particles having a size of 1 nm to 10 nm, 0% to 7% stabilisers and 0% to 3% adjuvants and the energy input by means of ultrasound takes place in the power range of at least 500 Ws/ml.

This thermal storage battery is preferably one in which component A additionally contains a silanised and/or aminic isocyanate which effects a pre-cross-linking of the binder and the energy input by means of ultrasound takes place in the power range of at least 500 Ws/ml.

This thermal storage battery is preferably one in which the nanoscalable fillers added to component B and/or in the form of a dispersion of nanoscaled fillers form specific properties in the plastic which after curing effect a variation (improvement) of the surface hardness, the abrasiveness, the UV stability, the increase in the thermal conductivity and serve to achieve surface effects such as the direct coupling to the entire infrared spectrum in the wavelength range of 780 mm to 1 mm.

In addition, the thermal storage battery is preferably one in which a blocked aminic light stabiliser is used as an additive for UV stabilisation.

Furthermore, the thermal storage battery is preferably one in which nanoscalable bone ash and mixtures thereof are used as flame retardants and the energy input by means of ultrasound takes place in the power range of at least 500 Ws/ml.

In addition, the thermal storage battery is one in which chemical aggregates having an affinity to gases and/or an internal or external release agent which reduces the adhesiveness to a mould wall, which bring about a thixotropic influence and/or have a moisture-content-reducing character in the reactive component B, are used in the solvent-free freely mouldable liquid plastic for promoting the workability of the coating material as adjuvants for deaeration and defoaming.

The invention additionally relates to a thermal transmitter as a matrix of semiconductor chips which are doped according to the Peltier-Seebeck effect, which are arranged geometrically freely between a thermal storage battery and a thermal diffuser for generating electrical energy or for energy conversion of thermal and electrical energy, wherein the thermal transmitter is necessarily arranged between heat source and heat sink and otherwise absolute creative freedom exists.

The invention further relates to a thermal diffuser which is a metallic or non-metallic heat conductor which comprises the thermal closure element according to the invention and/or the thermal storage battery according to the invention and which is cooled in a pulsed manner.

This thermal diffuser is preferably one which comprises a cooling system according to the Stemke system as pulsed cooling.

The invention further relates to a thermal generator according to the thermoelectric principle wherein a necessarily high flux (thermomotive force—TMF) through a semiconductor chip constructed according to the Peltier-Seebeck effect is achieved.

This thermal generator preferably comprises in accordance with the invention:

a thermal storage battery according to the invention,

a thermal transmitter according to the invention,

a thermal diffuser according to the invention

and optionally a thermal closure element according to the invention.

The invention additionally relates to a method for producing and processing a solvent-free freely mouldable liquid plastic based on a hydroxylene and/or aminofunctional reaction partner for isocyanate, wherein nanoscalable fillers can be added to the binder as component B, then at least one additive and at least one adjuvant, and the energy input by means of ultrasound takes place in the power range of at least 500 Ws/ml, and then for processing before spraying in the spraying method under pressure by component B, component A is added to component B as cross-linking agent by the injector principle and at the same time both components are homogenised and then an ultrafine distribution of the coating material with very little overspray is achieved by means of high-precision piston metering systems or similar systems having mechanically self-cleaning spray mixing heads and is applied to the provided mould wall and polymerised there in a short time to give a polyurethane or polyurea.

This method is preferably one in which chemical aggregates having an affinity to gases and/or an internal or external release agent which reduces the adhesiveness to a mould wall, which bring about a thixotropic influence and/or have a moisture-content-reducing character in the reactive component B, are used in the solvent-free freely mouldable liquid plastic for promoting the workability of the coating material as adjuvants for deaeration and defoaming.

The invention additionally relates to the use of the thermal generator according to the invention as a geothermal probe, for energy conversion of secondary energy, for independent power supplies in mains-free areas and/or for the simultaneous recovery of thermal energy in the ratio of about 3:1 to electrical energy.

### BRIEF DESCRIPTION OF THE FIGURES

FIG. 1 shows a schematic diagram of a thermoelement

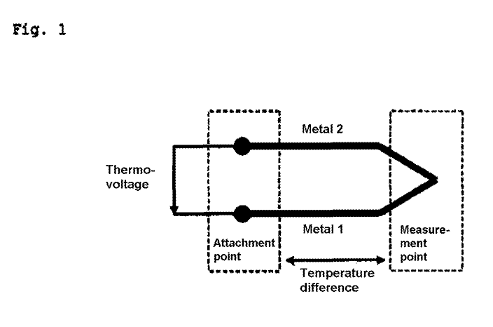

FIG. 2 shows a schematic diagram of a Peltier element

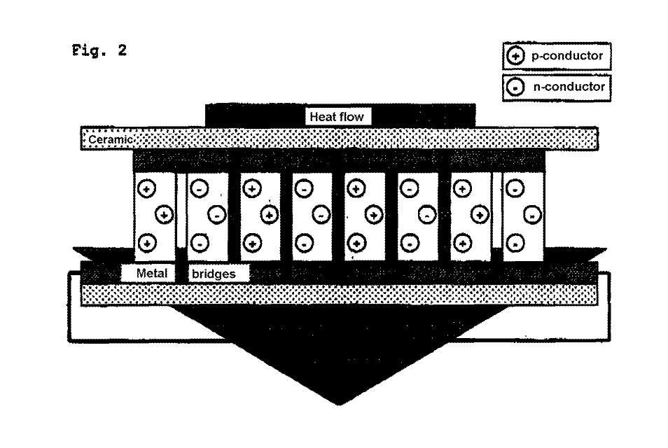

FIG. 3 shows the principle of a thermogenerator in accordance with the invention

FIG. 4 shows the cooling principle—heat pump

FIG. 5 shows the miniature cooling principle

FIG. 6 shows a schematic diagram of a roof application

FIG. 7 shows the electrical contacting of the thermal gates

FIG. 8 shows a block diagram of the entire cycle.

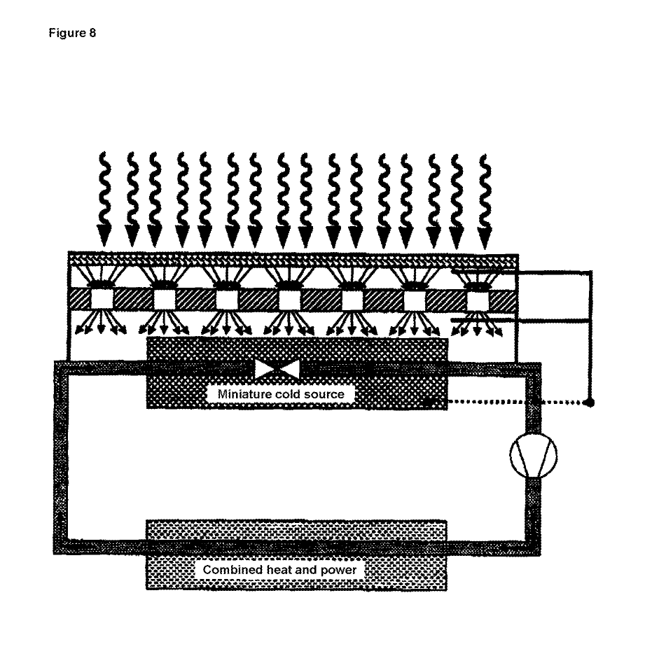

### TECHNICAL SOLUTION OF THE INVENTION

The Thermomotive Principle

The direct conversion of thermal energy into electrical energy is defined as the thermomotive principle or thermomotive force (TMF) and the inventive level is obtained from the combination of several known and new findings. The thermomotive force (TMF) is explained as the necessary thermal energy flux through a semiconducting Peltier element having the thermal transmitter at its centre and the extensive use of energy taking place by means of a controlled temperature gradient.

A thermogenerator (TEG) is described which can absorb a broad spectrum of infrared radiation, focuses this and passes it through a thermogate for power generation. The infrared radiation is then available in a heat sink for a further energy use.

Radiation Spectrum

Thermal radiation is designated as a part of the infrared radiation (IR radiation) which in turn is part of the optical radiation and therefore part of the electromagnetic spectrum. This adjoins the visible light in the direction of longer wavelengths. Its wavelength range extends from 780 nm to 1 mm. Infrared radiation is divided into the short-wavelength IR-A radiation having a wavelength range of 780 nm to 1400 nm, IR-B radiation (1400 to 3000 nm) and the long-wavelength partial range, the IR-C radiation (3000 nm to 1 mm).

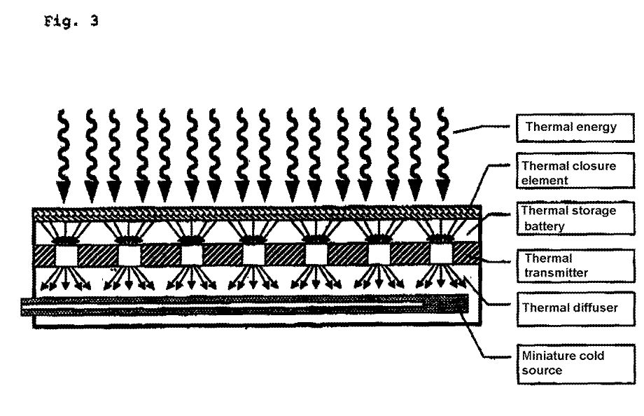

The principle of the thermogenerator is shown in FIG. 3. The thermogenerator consists of:

a thermal closure element (optional),

a thermal storage battery,

a thermal transmitter and

a thermal diffuser.

The thermal storage battery consists of a doped polymer matrix produced from an aliphatic isocyanate and a hydroxyl-group-containing and/or aminofunctional reaction partner. It ensures the functions of the thermal coupler and thermal conductor.

The thermal coupling inside the polymer matrix is accomplished, for example, with IR-absorbing pigments such as, for example, Minatec® 230 A-IR and/or nanoscale borides and/or similar nanoscale crystalline materials which serve as electron donors. These are, for example, platelet-shaped mica particles which are coated with an antimony-containing tin oxide layer or modified titanium dioxide nanoparticles which act as electron donors and enable strong absorption of infrared radiation in the wavelength range of 800 nm to 1 mm.

The thermal conductor has the task of ensuring heat conduction inside the polymer matrix. For this purpose carbon nanotubes (CNT) are incorporated into the polymer matrix. The thermal conductivity of the CNT, 6000 W/(m.K), is twice as high as the thermal conductivity of diamond and ensures a stable heat flow to the thermogate. The CNTs are stabilised in a special dispersion method in the matrix.

Composition of the Thermal Storage Battery

The thermal storage battery consists of a two-component coating material which comprises:
Component A: aliphatic isocyanate and/or mixtures thereof
Component B: binder wettable with component A consisting of:
   65 to 98% binder based on a hydroxyl-group-containing and/or aminofunctional reaction partners and/or mixtures thereof
   0 to 20% Minatec® 230 A-IR and/or a comparable substance according to the description,
   0 to 5% carbon nanotubes
   0 to 7% stabilisers
   0 to 3% adjuvants.

### PRODUCTION EXAMPLE 1

Up to 35% of aminofunctional binder is placed in the mixing container. The pigments, fillers and additives are added to this charge and mixed. The corresponding primary particles are produced by suitable energy input into this system, (e.g. agitator mill, ultrasonic generator). The remaining binder components are then added to the 100% base and mixed. The necessary temperature parameters should be noted depending on the pigments, fillers and additives used. Otherwise the person skilled in the art can make the selection on the basis of the generally known prior art, possibly after carrying out suitable series of tests.

Depending on the area of application of the thermogenerator, nanoscale and/or nanoscalable raw materials can be added to the thermal storage battery on the formulation side to improve the UV stability, to increase the surface hardness and therefore the abrasiveness, or also additives for protection from moss growth.

The production of the nanoparticles or the separation and homogenisation of the CNT's is accomplished by means of energy input by means of ultrasound in the range of 500 to 2000 W.

The thermal storage battery in accordance with the invention ensures higher than 90% coupling/absorption of IR radiation and relaying to the thermogate.

Surface Shape of the Thermal Storage Battery

The outer surface of the thermal storage battery can be freely shaped or configured, e.g. in the form of micro-calottes in order to achieve absorption of thermal radiation which is as free from scattering as possible. At the same time the surface shape should prevent the renewed emission of thermal radiation. For specific applications it can be logical and useful to integrate a thermal closure element on the surface.

This thermal closure element allows a temperature-guided opening of the surface of the thermal storage battery. A polymer is also used to implement this thermal closure element, as has already been described above. However, in this formulation the thermal functional materials are replaced by thermochromic pigments which pass through a reversible change in state of aggregation depending on the external temperature and therefore expose or cover the thermal coupling layer. As a result, stored energy is obtained in the system and can still be used after a drop in the external temperature.

The thermal closure element consists of a two-component coating material which comprises:
Component A: aliphatic isocyanate and/or mixtures thereof
Component B: binder wettable with component A consisting of:
   80 to 99% binder based on a hydroxyl-group-containing and/or aminofunctional reaction partners and/or mixtures thereof
   up to a maximum of 10% thermochromic pigment
   0 to 7% stabilisers
   0 to 3% adjuvants.

The thermal closure element is produced by analogy with the production example for the thermal storage battery.

The Thermal Transmitter

The thermal transmitter is the actual energy converter. It consists of the thermal barrier in which the thermal gates are embedded. Both materials are selected with regard to their thermal conductivity. Whilst the thermogates have a very high thermal conductivity, the thermal barrier consists of a material having the lowest possible thermal conductivity. Consequently, the thermal energy is forcibly passed through the thermal gates and thereby converted into electrical energy.

The thermal barrier of the thermal transmitter serves to ensure the energy flux of the thermal energy to the thermal gate in which case the smallest possible scattered radiation, conduction or convection should occur adjacent to the gate. At the same time, the barrier layer is the basis for the electrical contact plane. This layer consists of very poor heat conductors such as, for example, ceramic, epoxy-resin-bound glass fabrics and similar.

The thermogate consists of a semiconductor chip, the Peltier element. This is embedded in matrix form in the barrier depending on the energy supply. The thermal coupling to the diffuser is accomplished by means of a heat-conducting adhesive. The distance between the lines and the columns is determined by the available supply. The minimum distance is about 1 mm.

In the thermal transmitter in accordance with the invention it is important to specifically drive the heat through the thermogate (Peltier element). For this purpose a large thermal difference (temperature gradient) must exist between both sides of the thermogate.

The Thermal Diffuser

The thermal diffuser primarily has the task of ensuring the thermal flow with a high efficiency. For this purpose a miniature cold source e.g. according to the Stemke principle is arranged directly behind the thermogate. As a result, a continuously uniformly high temperature gradient is produced and the energy can flow. The material of the diffuser must in turn be characterised by a high thermal conductivity. In addition to metals such as, for example, aluminium or copper, CNT doped polymers can also be used.

The thermal diffuser in the form of a CNT-doped polymer consists of a two-component coating material which comprises:
Component A: aliphatic isocyanate and/or mixtures thereof
Component B: binder wettable with component A consisting of:
   at least 85% binder based on a hydroxyl-group-containing and/or aminofunctional reaction partners and/or mixtures thereof
   up to a maximum of 10% carbon nanotubes
   0 to 7% stabilisers
   0 to 3% adjuvants.

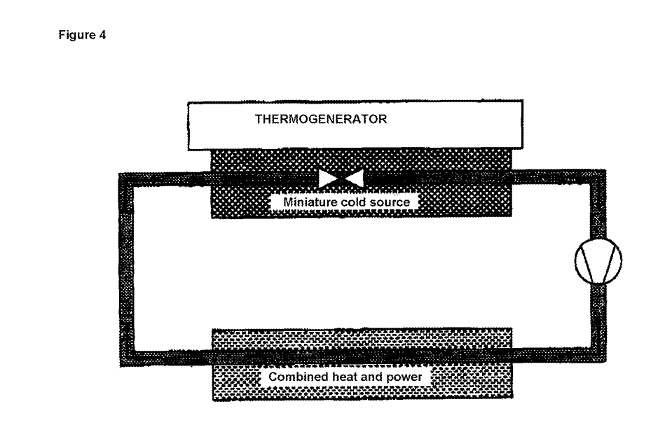

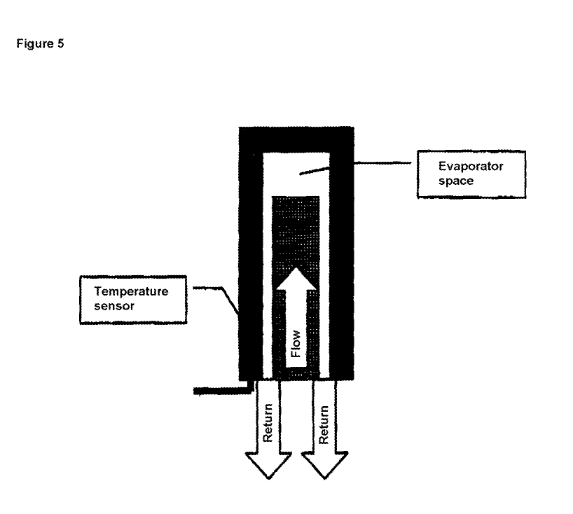

The technical design of the thermal diffuser is shown in FIGS. 4 and 5. The thermal diffuser operates, for example, with pulsed cold energy. In the geothermal application these can also be simple heat exchanger media such as, for example, water. The temperature regulation is accomplished by means of PD regulators which continuously detect the gradient between the storage battery and the diffuser and thus ensure the respective cold requirement in the diffuser.

In order to achieve the highest possible energy generation efficiency, the thermogenerator must be insulated from external heat irradiation at the back. Used for this purpose is a polyurethane-based insulating material which achieves a good insulating effect as a result of a very low thermal conductivity. At the same time, the insulation layer serves as the basis for attaching the thermogenerator to roof surfaces or similar.

In addition to the electrical energy, the heat forced through the thermogate is recovered by means of combined heat and power (see FIG. 4).

Electrical Contacting of the Thermogate

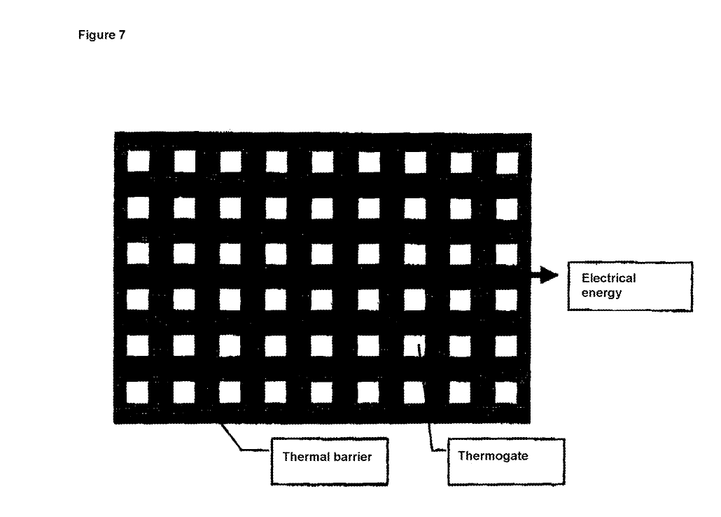

The electrical contacting is accomplished directly in the transmitter layer along the thermal barrier. The circuit matrix is determined by the performance chart and the ratio of voltage to current. The DC voltage produced can be stored by means of electric storage batteries or supplied to the power grid via inverters. (see FIG. 7)

Cryogenic Contacting of the Thermogates

In order to ensure a constantly high temperature gradient between storage battery layer and diffuser layer, a plurality of cold sources must be coupled together according to the STEMKE principle depending on the size of the thermogenerator. The connection is made via low-loss quick couplings.

### INDUSTRIAL APPLICABILITY

The thermogenerator of the present invention can be configured freely in its external shape. As a result, it can be used in manifold ways:

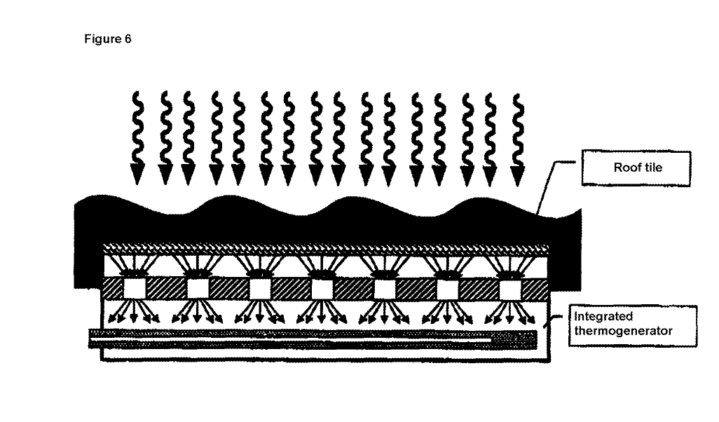

Examples:
Use of the inventive solution as a roof or facade element of a building for energy use of thermal energy in the form of thermal radiation (solar radiation etc.) (see FIG. 6)
Use of the inventive solution as an exterior bodywork element of a vehicle for energy use of thermal energy in the form of thermal radiation (solar radiation etc.)
Use of the apparatus as a geoprobe for energy use of thermal energy in the form of subterranean thermal radiation.
Use of the apparatus as an element in the environment of a heat source (e.g. motor) for energy use of thermal energy in the form of convection.

### Advantages of the Invention

The use of the permanently available alternative sources of thermal energy according to the description in accordance with the invention involves the timely generation of electrical energy and use of thermal energy.

By collecting and concentrating thermal energy in accordance with the description, appreciable new resources of energy use are opened up.

1. A thermogenerator comprising a thermal transmitter arranged between a thermal storage battery and a thermal diffuser.

2. The thermogenerator according to claim 1, wherein the transmitter forms a thermal barrier with Peltier elements embedded therein, acting as thermal gates between the storage battery and the diffuser.

3. The thermogenerator according to claim 1, wherein the Peltier elements are connected to one another along the thermal barrier according to a circuit matrix which is related to the performance chart and the ratio of voltage and current.

4. The thermogenerator according to claim 1, wherein the diffuser is fitted with at least one cold source and is preferably cooled in a pulsed manner.

5. The thermogenerator according to claim 4, wherein a plurality of miniature cold sources which ensure pulse-like cooling and are preferably coupled to one another by means of low-loss quick couplings.

6. The thermogenerator according to claim 1, wherein a PD regulator for continuously detecting and ensuring the temperature gradient existing between the storage battery and the diffuser.

7. The thermogenerator according to claim 1, wherein a combined heat and power for recovery of the heat forced through the transmitter.

8. The thermogenerator according to claim 1, wherein a thermal closure element disposed on the surface of the storage battery facing away from the transmitter, which closure element ensures a temperature-guided opening of the surface of the storage battery.

9. The thermogenerator according to claim 8, wherein the closure element consists of a solvent-free plastic which is formed from two reactive components, wherein component A consists of an aliphatic isocyanate and/or mixtures thereof and component B consists of an 80 to 99% fraction of binder wettable with component A, based on a hydroxylene and/or aminofunctional reaction partner and/or mixtures thereof, and wherein component B contains a maximum fraction of 10% thermochromic pigments, 0% to 7% stabilisers and 0% to 3% of adjuvants.

10. The thermogenerator according to claim 9, wherein nanoscalable fillers in powder form and/or in the form of a dispersion are additionally added to component B, which fillers form specific properties in the coating material which after curing effect a change in the surface hardness, the abrasiveness and/or the UV stability and/or serve to achieve surface effects and to achieve a fungicidal or an antifouling effect.

11. The thermogenerator according to claim 1, wherein the thermal storage battery consists of a solvent-free plastic which is formed from two reactive components, wherein component A consists of an aliphatic isocyanate and/or mixtures thereof and component B consists of a 65% to 98% fraction of binder wettable with component A, based on a hydroxylene and/or aminofunctional reaction partner and/or mixtures thereof, and wherein component B contains a fraction of 0.00025% to 5% functionalised and/or non-functionalised carbon nanotubes, 0% to 20% of nanoscalable fillers and/or a dispersion of nanoscaled fillers in the form of primary particles having a size of 1 nm to 10 nm, 0% to 7% stabilisers and 0% to 3% adjuvants and the energy input by means of ultrasound takes place in the power range of at least 500 Ws/ml.

12. The thermogenerator according to claim 11, wherein component A additionally contains a silanised and/or aminic isocyanate which effects a pre-cross-linking of the binder and the energy input by means of ultrasound takes place in the power range of at least 500 Ws/ml.

13. The thermogenerator according to any one of claims 11, wherein the nanoscalable fillers added to component B and/or in the form of a dispersion of nanoscaled fillers produce specific properties in the plastic which after curing effect a variation (improvement) of the surface hardness, the abrasiveness, the UV stability, the increase in the thermal conductivity and serve to achieve surface effects such as the direct coupling to the entire infrared spectrum in the wavelength range of 780 mm to 1 mm.

14. The thermogenerator according to claim 11, wherein a blocked aminic light stabiliser is used as an additive for UV stabilisation.

15. The thermogenerator according to claim 11, wherein nanoscalable bone ash and mixtures thereof are used as flame retardants and the energy input by means of ultrasound takes place in the power range of at least 500 Ws/ml.

16. The thermogenerator according to claim 11, wherein chemical aggregates having an affinity to gases and/or an internal or external release agent which reduces the adhesiveness to a mould wall, which bring about a thixotropic influence and/or have a moisture-content-reducing character in the reactive component B, are used in the solvent-free plastic for promoting the workability of the coating material as adjuvants for deaeration and defoaming.

17. The thermogenerator according to claim 10, wherein the closure element and/or the storage battery can be obtained by adding the nanoscalable fillers to the binder as component B, then at least one additive and at least one adjuvant, and the energy input by means of ultrasound takes place in the power range of at least 500 Ws/ml, and then for processing before spraying in the spraying method under pressure by component B, component A is added to component B as cross-linking agent by the injector principle and at the same time both components are homogenised and then an ultrafine distribution of the coating material with very little overspray is achieved by means of high-precision piston metering systems or similar systems having mechanically self-cleaning spray mixing heads and is applied to the provided mould wall and polymerised there in a short time to give a polyurethane or polyurea.

18. The thermogenerator according to claim 17, wherein the closure element and/or the storage battery can be obtained by using chemical aggregates having an affinity to gases and/or an internal or external release agent which reduces the adhesiveness to a mould wall, which bring about a thixotropic influence and/or have a moisture-content-reducing character in the reactive component B, in the solvent-free plastic for promoting the workability of the coating material as adjuvants for deaeration and defoaming.

19-22. (canceled)
